(19) United States
(12) Patent Application Publication
(10) Pub. No.: US 2013/0207072 A1
(43) Pub. Date: Aug. 15, 2013

(54) OPTICAL STRUCTURE AND LIGHT EMITTING DEVICE

(71) Applicants: Wintek (China) Technology Ltd., (US); Wintek Corporation, (US)

(72) Inventors: Chia-Hsiung Chang, Tainan City (TW); Yan-Yu Su, Changhua County (TW); Fa-Chen Wu, Taichung City (TW)

(73) Assignees: WINTEK CORPORATION, Taichung City (TW); Wintek (China) Technology Ltd., Dongguan City (CN)

(21) Appl. No.: 13/740,271

(22) Filed: Jan. 14, 2013

(30) Foreign Application Priority Data
Feb. 9, 2012 (TW) 101104183

(51) Int. Cl. H01L 33/06

(52) U.S. Cl. CPC H01L 33/06
USPC 257/13

(57) ABSTRACT

A light emitting device includes a substrate, a light emitting unit, and a first optical structure. The light emitting unit is disposed on a top surface of the substrate. The first optical structure is disposed on the light emitting unit. The first optical structure includes a plurality of first nanostructures and a plurality of first quantum dot units. Each of the first quantum dot units is disposed in the first nanostructure. The light emitting unit is used to generate a first color light. Each of the first quantum dot units is used to be excited by the first color light to generate a second color light different from the first color light.

### BACKGROUND OF THE INVENTION

1. Field of the Invention

The present invention relates to an optical structure and a light emitting device, and more particularly, to a light emitting device including an optical structure. Quantum dot units disposed in nanostructures of the optical structure are excited by light from a light emitting unit to generate light with different colors.

2. Description of the Prior Art

Because of certain advantages, such as low power consumption, long life time, low driving voltage, and short response time, light emitting diodes (LED) have been widely employed in traffic signals, lighting devices, and many electronic products.

In conventional light emitting devices with light emitting diodes, LEDs capable of providing light with different colors are mixed to generate light with desired color. However, each of the LEDs capable of providing light with different colors has to be respectively modified to obtain the appropriate color mixing and many problems may accordingly occur. Therefore, light emitting devices with single type LED are developed recently. In the light emitting device with single type LED, a fluorescent layer or a quantum dot layer is generally used to be excited by light from the single type LED to generate light with different colors. In some of the light emitting devices described above, quantum dots may be directly added into a filling material of the LED or an organic LED structure so as to simplify the structure. However, the luminous efficiency of these light emitting devices may be relatively low because the quantum dots in the filling material will not be excited adequately. Conventional light extracting structures, such as rough surfaces or scattering particles, may still have to be employed to improve the luminous efficiency, but the improvement will be limited because the light generated by the excited quantum dot is insufficient.

### SUMMARY OF THE INVENTION

It is one of the objectives of the present invention to provide an optical structure and a light emitting device. Quantum dot units are disposed in nanostructures of the optical structure or a substrate. The quantum dot units are excited by light generated from a light emitting unit to generate light with different colors. The luminous efficiency of the light emitting device may be accordingly enhanced.

To achieve the purposes described above, a preferred embodiment of the present invention provides a light emitting device. The light emitting device includes a substrate, a light emitting unit, and a first optical structure. The substrate has a top surface and a bottom surface. The light emitting unit is disposed on the top surface of the substrate. The first optical structure is disposed on the light emitting unit. The first optical structure includes a plurality of first nanostructures and a plurality of first quantum dot units. Each of the first quantum dot units is disposed in the first nanostructure. The light emitting unit is used to generate a first color light. Each of the first quantum dot units is used to be excited by the first color light to generate a second color light different from the first color light.

To achieve the purposes described above, a preferred embodiment of the present invention provides an optical structure. The optical structure includes a base material, a plurality of nanostructures, and a plurality of first quantum dot units. The nanostructures are disposed on a surface of the base material. The first quantum dot units are disposed in the nanostructures.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a light emitting device according to a first preferred embodiment of the present invention.

FIGS. 2-5 are schematic diagrams illustrating top-views of first nanostructures in the light emitting device according to the first preferred embodiment of the present invention.

FIG. 6 is a schematic diagram illustrating a light emitting device according to a second preferred embodiment of the present invention.

FIG. 7 is a schematic diagram illustrating a light emitting device according to a third preferred embodiment of the present invention.

FIG. 8 is a schematic diagram illustrating a light emitting device according to a fourth preferred embodiment of the present invention.

### DETAILED DESCRIPTION

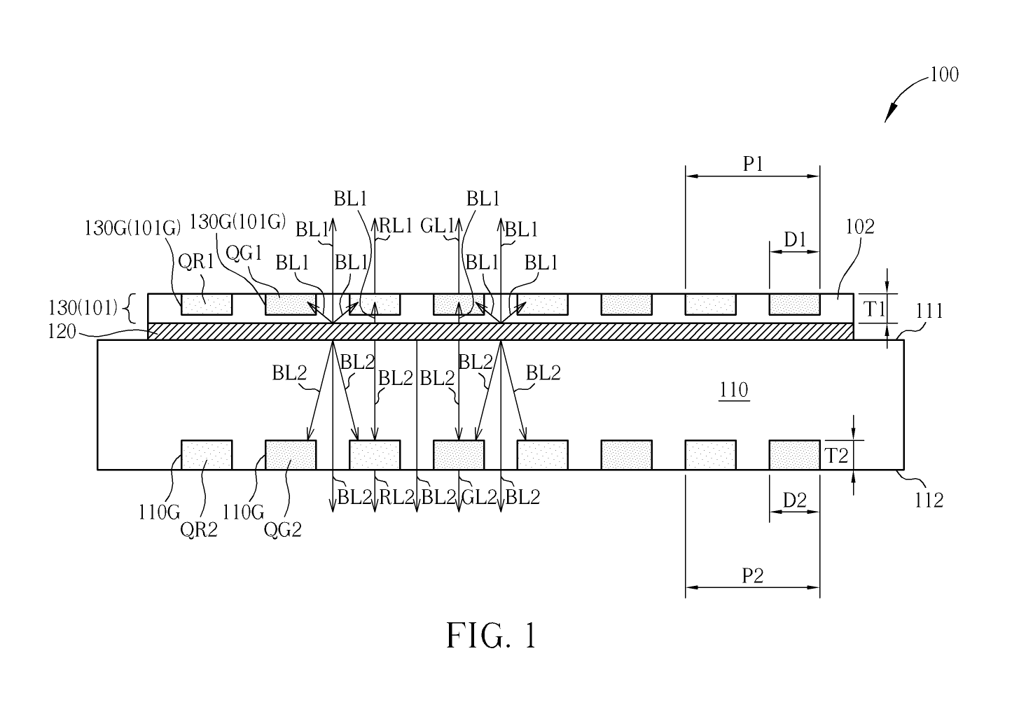

Please refer to FIG. 1. FIG. 1 is a schematic diagram illustrating a light emitting device according to a first preferred embodiment of the present invention. Please note that the figures are only for illustration and the figures may not be to scale. The scale may be further modified according to different design considerations. As shown in FIG. 1, the first preferred embodiment of the present invention provides a light emitting device 100. The light emitting device 100 includes a substrate 110, a light emitting unit 120, and a first optical structure 130. The substrate 110 has a top surface 111 and a bottom surface 112. The light emitting unit 120 is disposed on the top surface 111 of the substrate 110. The first optical structure 130 is disposed on the light emitting unit 120. The first optical structure 130 includes a plurality of first nanostructures 130G, a plurality of first quantum dot units QR1, and a plurality of second quantum dot units QG1. Each of the first quantum dot units QR1 and each of the second quantum dot units QG1 are respectively disposed in different first nanostructures 130G. In this embodiment, the first quantum dot units QR1 and the second quantum dot units QG1 preferably include group II-VI compounds, such as zinc cadmium sulphide (ZnCdS), zinc sulphide (ZnS), zinc selenide (ZnSe), zinc telluride (ZnTe), cadmium sulphide (CdS), cadmium selenide (CdSe), cadmium Telluride (CdTe), cadmium sulphoselenide (CdSSe), zinc cadmium sulfide (ZnCdS), zinc Cadmium Selenium (ZnCdSe), or a composite of the above-mentioned compounds, but not limited thereto. Additionally, in this embodiment, each of the first nanostructures 130G in the first optical structure 130 may be formed by a nano printing process or a roll-to-roll process, and each of the first nanostructures 130G may then be filled with quantum dot materials to form the first quantum dot units QR1 and the second quantum dot units QG1, but the present invention is not limited to this and other appropriate processes may also be employed to form the first nanostructures 130G, the first quantum dot units QR1, and the second quantum dot units QG1. It is worth noting that the substrate 110 in this embodiment may preferably include a glass substrate or a plastic substrate, but not limited thereto. In addition, a refractive index of the first optical structure 130 is preferably between 1.5 and 1.9 when a refractive index of the light emitting unit 120 is generally between 1.7 and 1.9 so as to avoid the light generated from the light emitting unit 120 from being totally reflected by the first optical structure 130. The light emitting unit 120 is used to generate a first color light BL1 and a first color light BL2. The first color light BL1 substantially irradiates toward a direction away form the substrate 110 and the first color light BL2 substantially irradiates toward the substrate 110. Each of the first quantum dot units QR1 is used to be excited by the first color light BL1 to generate a second color light RL1 which is different from the first color light BL1. Each of the second quantum dot units QG1 is used to be excited by the first color light BL1 to generate a third color light GL1 which is different from the first color light BL1 and the second color light RL1. In this embodiment, the first color light BL1, the second color light RL1, and the third color light GL1 are preferably blue light, red light, and green light respectively, and the light emitting device 100 may then be regarded as a white light emitting device, but the present invention is not limited to this. Components of the light emitting unit 120, the first quantum dot units QR1, and the second quantum dot units QG1 may be respectively modified to generate light with different colors for other color mixture demands and other considerations. In other words, the light emitting unit 120 in this embodiment may preferably include a blue light emitting diode or a blue organic light emitting diode, the first quantum dot units QR1 may preferably include red quantum dot units, and the second quantum dot units QG1 may preferably include green quantum dot units, but not limited thereto.

In the light emitting device 100 in this embodiment, the substrate 110 may include a plurality of second nanostructures 110G, a plurality of third quantum dot units QR2, and a plurality of fourth quantum dot units QG2. Each of the second nanostructures 110G is disposed at the bottom surface 112 of the substrate. Each of the third quantum dot units QR2 and each of the fourth quantum dot units QG2 are respectively disposed in different second nanostructures 110G. Each of the third quantum dot units QR2 is used to be excited by the first color light BL2 to generate a fourth color light RL2, and each of the fourth quantum dot units QG2 is used to be excited by the first color light BL2 to generate a fifth color light GL2. In this embodiment, the first color light BL2, the fourth color light RL2, and the fifth color light GL2 preferably are blue light, red light, and green light respectively, but not limited thereto. In other words, the fourth quantum dot units QR2 may preferably include red quantum dot units, and the fifth quantum dot units QG2 may preferably include green quantum dot units, but not limited thereto. Additionally, in this embodiment, each of the second nanostructures 110G may be formed on the substrate 110 by a process such as a photo etching process, and each of the second nanostructures 110G may then be filled with quantum dot materials to form the third quantum dot units QR2 and the fourth quantum dot units QG2, but the present invention is not limited to this and other appropriate processes may also be employed to form the second nanostructures 110G, the third quantum dot units QR2, and the fourth quantum dot units QG2.

As shown in FIG. 1, the light emitting unit 120 may be employed to generate the first color light BL1 and the first color light BL2. The first color light BL1 substantially irradiates toward a direction away form the substrate 110 and the first color light BL2 substantially irradiates toward the substrate 110. Each of the first quantum dot units QR1 is used to be excited by the first color light BL1 to generate the second color light RL1, and each of the second quantum dot units QG1 is used to be excited by the first color light BL1 to generate the third color light GL1. A part of the first color light BL1, which does not irradiate directly toward the first quantum dot units QR1 and the second quantum dot units QG1, may be mixed with the second color light RL1 and the third color light GL1 so as to generate a color mixture effect on a surface of the first optical structure or an upper part of the light emitting device 100. According to the same rule, each of the third quantum dot units QR2 in the second nanostructures 110G is used to be excited by the first color light BL2 to generate the fourth color light RL2, and each of the fourth quantum dot units QG2 is used to be excited by the first color light BL2 to generate a fifth color light GL2. A part of the first color light BL2, which does not irradiate directly toward the third quantum dot units QR2 and the fourth quantum dot units QG2, may be mixed with the fourth color light RL2 and the fifth color light GL2 so as to generate a color mixture effect on the bottom surface 112 of the substrate or a lower part of the light emitting device 100. In other words, the color mixture illumination effect may be generated on both the upper part and the lower part of the light emitting device 100, and the light emitting device 100 may be a dual-side illumination device. For example, when the first color light BL1, the second color light RL1, and the third color light GL1 are respectively blue light, red light, and green light; and the first color light BL2, the fourth color light RL2, and the fifth color light GL2 are respectively blue light, red light, and green light, the light emitting device 100 may be regarded as a dual-side white light emitting device. It is worth noting that, in other preferred embodiments of the present invention, a single side color mixture effect may also be obtained by disposing only the first optical structure 130, which includes the first quantum dot units QR1 and the second quantum dot units QG1, or only the third quantum dot units QR2 and the fourth quantum dot units QG2.

In addition, as shown in FIG. 1, a width D1 of each of the first nanostructures 130G and a width D2 of each of the second nanostructures 10G are preferably respectively between 200 nanometers and 800 nanometers, a period P1 between the first nanostructures 130G and a period P2 between the second nanostructures 110G are preferably respectively between 200 nanometers and 800 nanometers, and a depth T1 of each of the first nanostructures 130G and a depth T2 of each of the second nanostructures 110G are preferably respectively between 40 nanometers and 200 nanometers so as to generate a better display effect, but the present invention is not limited thereto. The width, the period, and the depth of each of the nanostructures may be further modified to generated different optical effects.

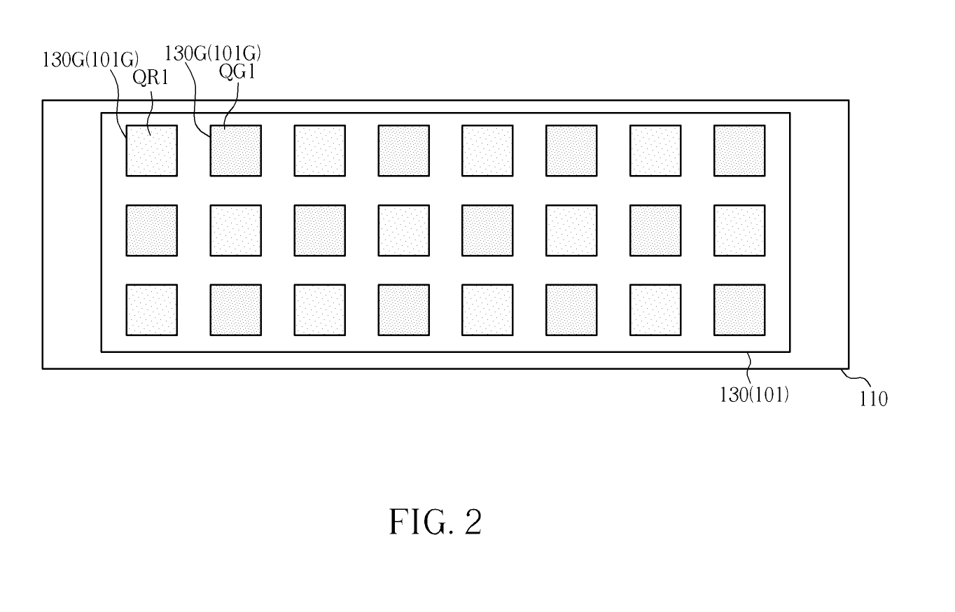

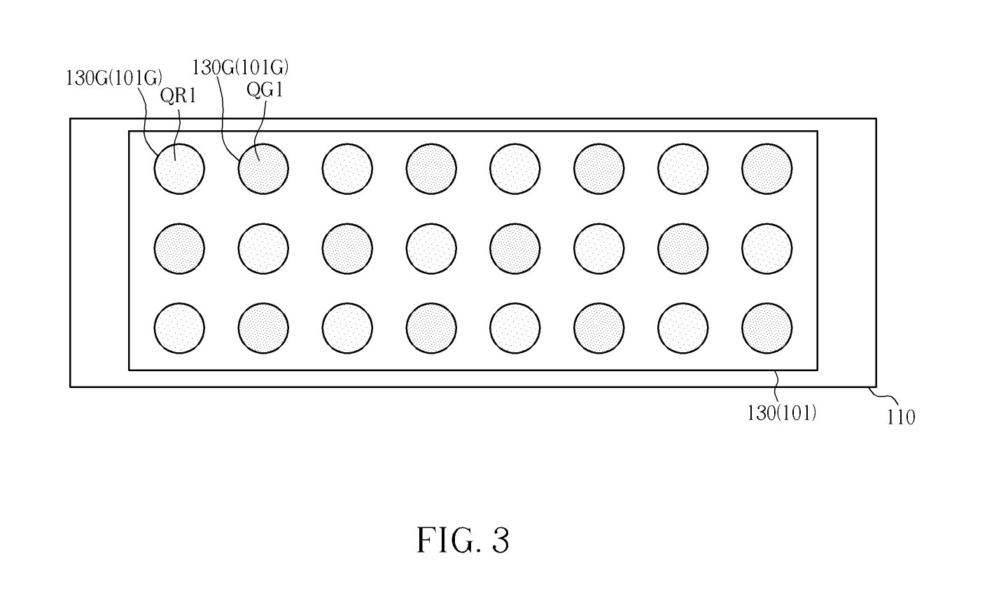

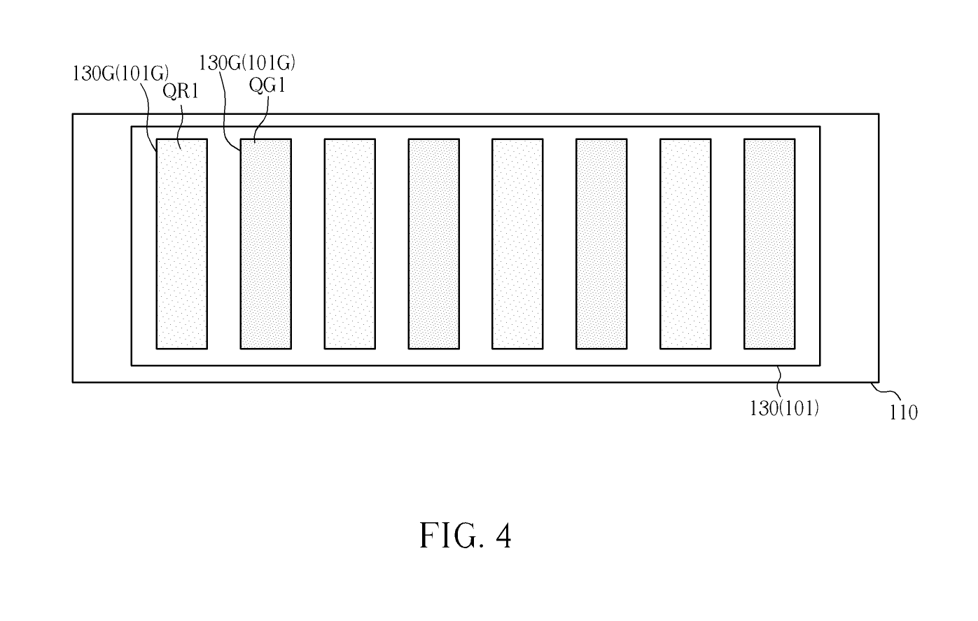

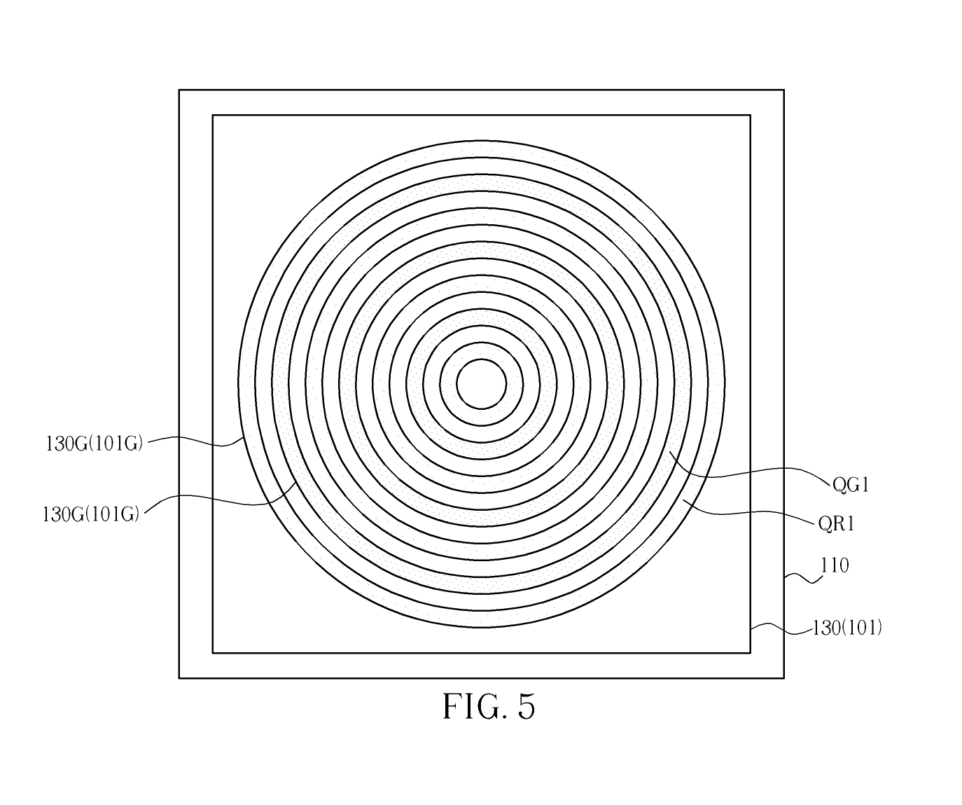

Please refer to FIGS. 2-5. FIGS. 2-5 are schematic diagrams illustrating top-views of the first nanostructures in the light emitting device according to the first preferred embodiment of the present invention. As shown in FIGS. 2-5, the first nanostructures 130G in the light emitting device 100 of this embodiment may preferably include rectangular nanostructures (as shown in FIG. 2), circle nanostructures (as shown in FIG. 3), stripe nanostructures (as shown in FIG. 4), concentric nanostructures (as shown in FIG. 5), or other nanostructures with appropriate shapes so as to generate better light mixture or white light emitting effect. The first quantum dot units QR1 and the second quantum dot units QG1 are preferably disposed in the first nanostructures 130G uniformly so as to generate a better light mixture effect, but not limited thereto. Designs of patterns of the second nanostructures 110G and allocations of the corresponding quantum dot units are similar to the first nanostructures 130G and will not be redundantly described.

In addition, as shown in FIGS. 1-5, the present invention provides an optical structure 101. The optical structure 101 includes a base material 102, a plurality of nanostructures 101G, a plurality of first quantum dot units QR1 and a plurality of second quantum dot units QG1. The nanostructures 101G are disposed on a surface of the base material 102. The first quantum dot units are disposed in the nanostructures 101G. Each of the first quantum dot units QR1 and each of the second quantum dot units QG1 are respectively disposed in different nanostructures 101G. A refractive index of the optical structure 101 is between 1.5 and 1.9. The nanostructures 101G may include rectangular nanostructures (as shown in FIG. 2), circle nanostructures (as shown in FIG. 3), stripe nanostructures (as shown in FIG. 4), concentric nanostructures (as shown in FIG. 5), or other nanostructures with appropriate shapes. A width Dl of each of the nanostructures 101G is preferably between 200 nanometers and 800 nanometers, a period P1 between the nanostructures 101G is preferably between 200 nanometers and 800 nanometers, and a depth T1 of each of the nanostructures 101G is preferably between 40 nanometers and 200 nanometers, but the present invention is not limited thereto. The width, the period, and the depth of each of the nanostructures 101G may be further modified according to different considerations. Additionally, the materials properties of the components in the optical structure 101 are similar to those of the first optical structure 130 detailed above and will not be redundantly described. It is worth noting that the base material 102 may preferably include plastic materials, such as polyethylene terephthalate (PET), polyethersulfone (PES), polyimide (PI), polycarbonate (PC), polyethylene naphthalate (PEN), polymethyl methacrylate (PMMA), or other appropriate materials.

The following description will detail the different embodiments of the light emitting device in the present invention. To simplify the description, identical components in each of the following embodiments are marked with identical symbols. For making it easier to understand the differences between the embodiments, the following description will detail the dissimilarities among different embodiments and the identical features will not be redundantly described.

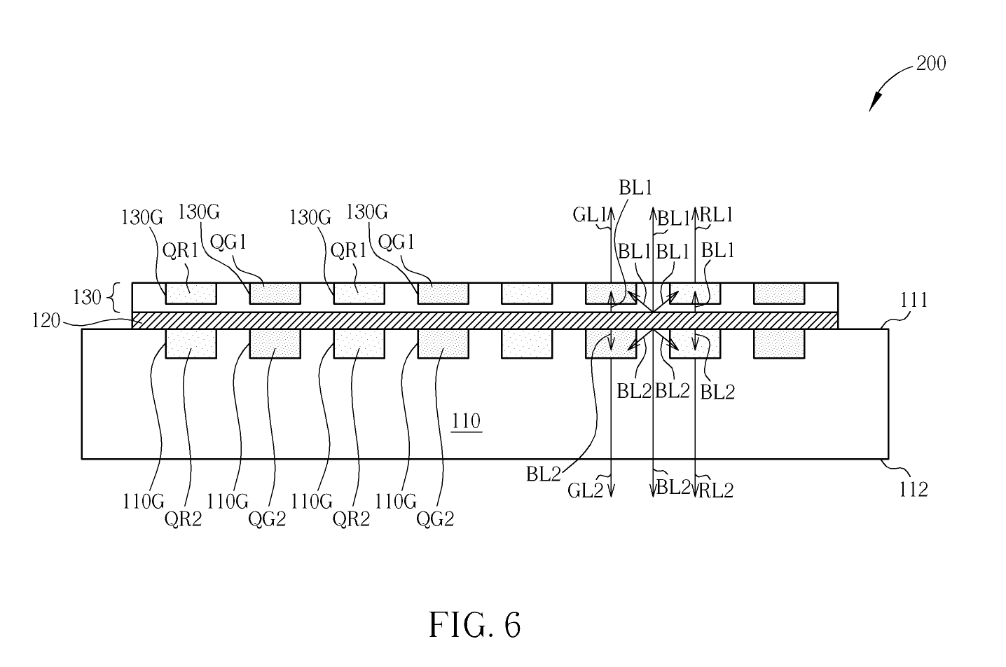

Please refer to FIG. 6. FIG. 6 is a schematic diagram illustrating a light emitting device according to a second preferred embodiment of the present invention. As shown in FIG. 6, the difference between a light emitting device 200 of this embodiment and the light emitting device 100 of the first preferred embodiment is that each of the second nanostructures 110G is disposed at the top surface 111 of the substrate 110. Each of the third quantum dot units QR2 and each of the fourth quantum dot units QG2 are respectively disposed in different second nanostructures 110G. Apart from the allocations of the second nanostructures 110G, the corresponding third quantum dot units QR2, and the corresponding fourth quantum dot units QG2 in this embodiment, the other components, allocations, material properties, and light emitting methods in this embodiment are similar to those of the light emitting device 100 in the first preferred embodiment detailed above and will not be redundantly described.

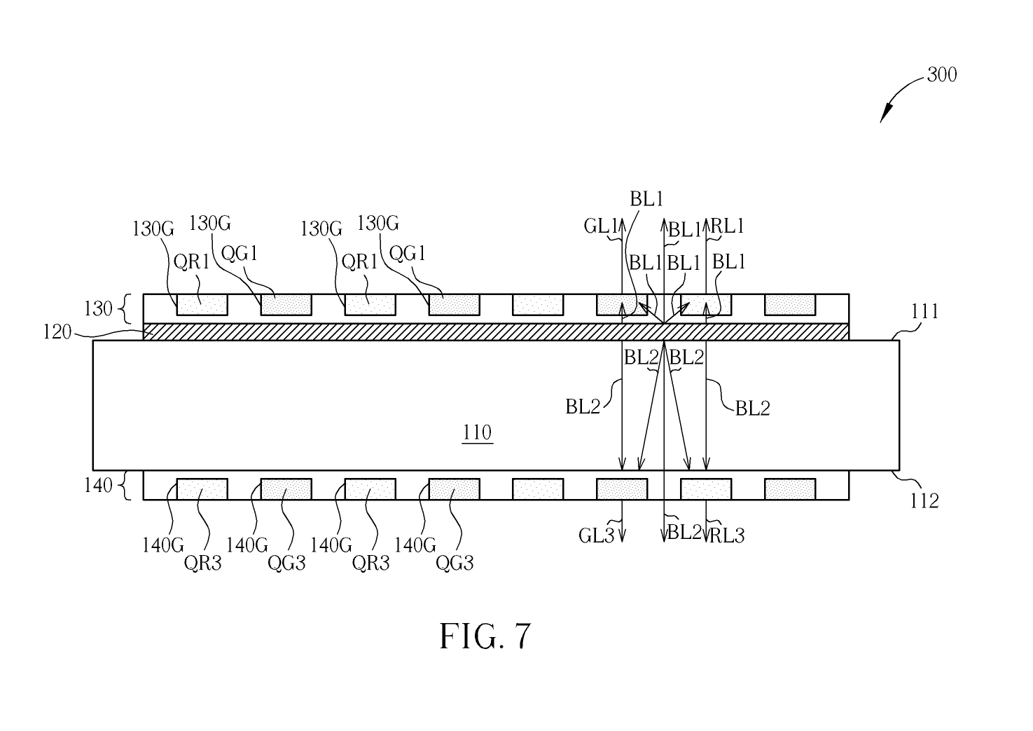

Please refer to FIG. 7. FIG. 7 is a schematic diagram illustrating a light emitting device according to a third preferred embodiment of the present invention. As shown in FIG. 7, the difference between a light emitting device 300 of this embodiment and the light emitting device 100 of the first preferred embodiment is that the light emitting device 300 further includes a second optical structure 140 disposed on the bottom surface 112 of the substrate 110. The second optical structure 140 includes a plurality of third nanostructures 140G, a plurality of fifth quantum dot units QR3, and a plurality of sixth quantum dot units QG3. Each of the fifth quantum dot units QR3 and each of the sixth quantum dot units QG3 are respectively disposed in different third nanostructures 140G. The structure, material properties, and manufacturing method of the second optical structure 140 in this embodiment are similar to those of the first optical structure 130 detailed above and will not be redundantly described. In the light emitting device 300 of this embodiment, a part of the first color light BL2, which is generated from the light emitting unit 120, may be used to excite the fifth quantum dot units QR3 and the sixth quantum dot units QG3 in the second optical structure 140 after passing through the substrate 110. Each of the fifth quantum dot units QR3 is used to be excited by the first color light BL2 to generate a sixth color light RL3, and each of the sixth quantum dot units QG3 is used to be excited by the first color light BL2 to generate a seventh color light GL3. In this embodiment, the first color light BL2, the sixth color light RL3, and the seventh color light GL3 preferably are blue light, red light, and green light respectively, but not limited thereto. A part of the first color light BL2, which does not irradiate directly toward the fifth quantum dot units QR3 and the sixth quantum dot units QG3, may be mixed with the sixth color light RL3 and the seventh color light GL3 so as to generate a color mixture effect on a lower part of the light emitting device 300. A refractive index of the second optical structure 140 is preferably between 1.5 and 1.9 so as to avoid the light generated from the light emitting unit 120 from being totally reflected by the second optical structure 140, but not limited thereto. It is worth noting that the fifth quantum dot units QR3 and the sixth quantum dot units QG3 in the second optical structure 140 are employed to generate the color mixture and illumination effect on the lower part of the light emitting device 300. The dual-side color mixture and illumination effect may be obtained without disposing nanostructures and quantum dot units inside the substrate 110, and the related manufacturing processes may accordingly be simplified.

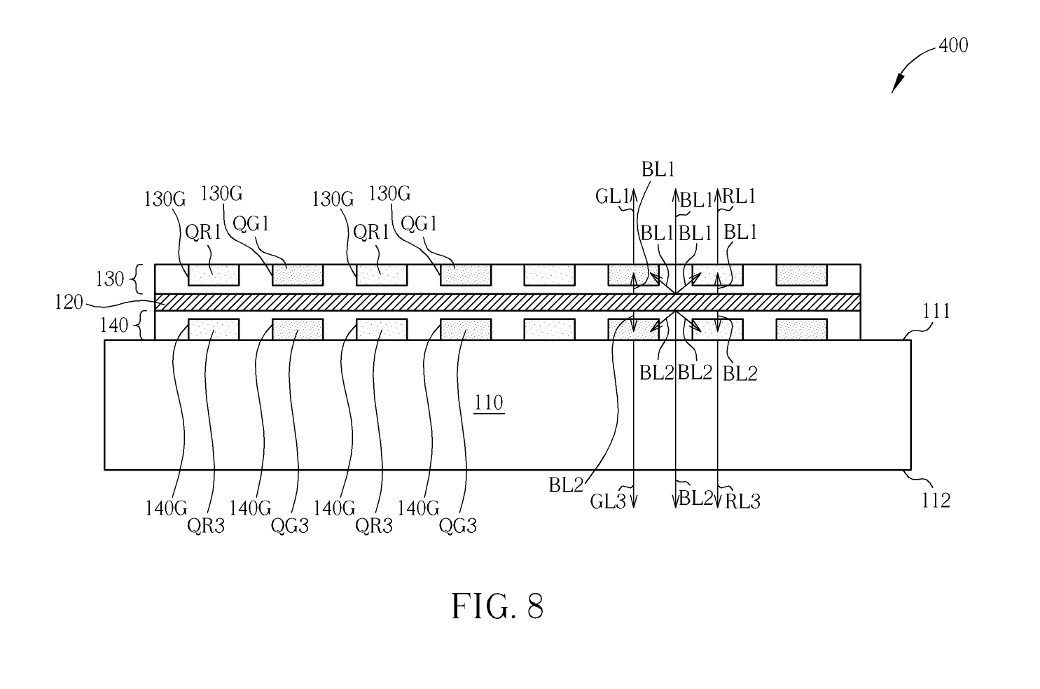

Please refer to FIG. 8. FIG. 8 is a schematic diagram illustrating a light emitting device according to a fourth preferred embodiment of the present invention. As shown in FIG. 8, the difference between a light emitting device 400 of this embodiment and the light emitting device 300 of the third preferred embodiment is that the second optical structure 140 in this embodiment is disposed between the substrate 110 and the light emitting unit 120. Apart from the allocation of the second optical structure 140 in this embodiment, the other components, allocations, material properties, and light emitting methods in this embodiment are similar to those of the light emitting device 300 in the third preferred embodiment detailed above and will not be redundantly described.

It is worth noting that apart from the first optical structure 130 described above, the optical structure in the present invention may also include the second optical structure 140 shown in FIG. 7 and FIG. 8. Furthermore, the substrate 110 shown in FIGS. 1-6, which includes the second nanostructures 110G, the corresponding third quantum dot units QR2 and the corresponding fourth quantum dot units QG2, may also be regarded as a variation embodiment of the optical structure in the present invention. In other words, the base material of the optical structure may also include a substrate or a film.

To summarize the above descriptions, in the light emitting device of the present invention, the quantum dot units are disposed in the nanostructures of the optical structure or the nanostructures of the substrate. The light with different colors may be generated by exciting the quantum dot units with the color light generated from the light emitting unit. The light with different colors may be mixed to generate desired color or white light illumination effect. It is worth noting that the quantum dot in the nanostructures may be excited more adequately and the luminous efficiency inside the light emitting device may be accordingly enhanced. The conventional light extracting structures may not be required to be employed with the light emitting device of the present invention. Of course, the luminous efficiency of the light emitting device may be further enhanced by disposing the light extracting structures. In addition, the manufacturing methods, the allocations, and the shapes of the nanostructures may be modified to generate the dual-side color mixture and illumination effect more efficiently.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A light emitting device, comprising:
a substrate, having a top surface and a bottom surface;
a light emitting unit, disposed on the top surface of the substrate; and
a first optical structure, disposed on the light emitting unit, the first optical structure comprises:
a plurality of first nanostructures; and
a plurality of first quantum dot units, disposed in the first nanostructures,
wherein the light emitting unit is used to generate a first color light, and each of the first quantum dot units is used to be excited by the first color light to generate a second color light different from the first color light.

2. The light emitting device of claim 1, wherein the first optical structure further comprises a plurality of second quantum dot units disposed in the first nanostructures, and each of the second quantum dot units is used to be excited by the first color light to generate a third color light different from the first color light and the second color light.

3. The light emitting device of claim 1, wherein the substrate further comprises:
a plurality of second nanostructures; and
a plurality of third quantum dot units and a plurality of fourth quantum dot units, respectively disposed in different second nanostructures,
wherein each of the third quantum dot units is used to be excited by the first color light to generate a fourth color light, and each of the fourth quantum dot units is used to be excited by the first color light to generate a fifth color light.

4. The light emitting device of claim 3, wherein the second nanostructures are disposed on the top surface of the substrate.

5. The light emitting device of claim 3, wherein the second nanostructures are disposed on the bottom surface of the substrate.

6. The light emitting device of claim 1, further comprising a second optical structure, the second optical structure comprising:
a plurality of third nanostructures; and
a plurality of fifth quantum dot units and a plurality of sixth quantum dot units, respectively disposed in different third nanostructures,
wherein each of the fifth quantum dot units is used to be excited by the first color light to generate a sixth color light, and each of the sixth quantum dot units is used to be excited by the first color light to generate a seventh color light.

7. The light emitting device of claim 6, wherein the second optical structure is disposed between the substrate and the light emitting unit.

8. The light emitting device of claim 6, wherein the second optical structure is disposed on the bottom surface of the substrate.

9. An optical structure, comprising:
a base material;
a plurality of nanostructures, disposed on a surface of the base material; and
a plurality of first quantum dot units, disposed in the nanostructures.

10. The optical structure of claim 9, further comprising a plurality of second quantum dot units disposed in the nanostructures.
